(19) United States
(12) Patent Application Publication
(10) Pub. No.: US 2026/0214962 A1
(43) Pub. Date: Jul. 23, 2026

(54) MEMORY DEVICES AND FABRICATING METHODS THEREOF

(71) Applicant: Yangtze Memory Technologies Co., Ltd., Wuhan (CN)

(72) Inventors: Bo Xu, Wuhan (CN); Bin Yuan, Wuhan (CN); Fan Gong, Wuhan (CN); Zhenyu Miao, Wuhan (CN); Jingyu Zhai, Wuhan (CN); Feng Wang, Wuhan (CN); Dongmen Song, Wuhan (CN)

(21) Appl. No.: 19/055,765

(22) Filed: Feb. 18, 2025

Related U.S. Application Data
(63) Continuation of application No. PCT/CN2025/072976, filed on Jan. 17, 2025.

(51) Int. Cl. H10D 64/66; H10B 12/00

(52) U.S. Cl. CPC H10D 64/666; H10B 12/05; H10B 12/315; H10B 12/488; H10D 64/662; H10D 64/667

(57) ABSTRACT

A disclosed memory device includes transistors. Each transistor includes a semiconductor body extending along a first direction; and a gate structure coupled with the semiconductor body. The gate structure extends along the first direction and includes a first conductive layer extending along the first direction and a second conductive layer in contact with the first conductive layer at the first direction. A first end of the first conductive layer is in contact with a second end of the second conductive layer, and a second end of the first conductive layer is away from the second end of the second conductive layer. A material of the second conductive layer is different from a material of the first conductive layer.

### CROSS-REFERENCE TO RELATED APPLICATIONS

This application is a continuation of International Application No. PCT/CN 2025/072976, filed on Jan. 17, 2025, which is hereby incorporated by reference in its entirety.

### TECHNICAL FIELD

The present disclosure generally relates to the field of semiconductor technology and, more particularly, to memory devices and fabricating methods thereof.

### BACKGROUND

Planar memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuit structures to facilitate the operations of the memory array.

### SUMMARY

Some aspects of the present disclosure provide a memory device including transistors. Each transistor includes a semiconductor body extending along a first direction and a gate structure coupled with the semiconductor body. The gate structure extends along the first direction and includes a first conductive layer extending along the first direction and a second conductive layer in contact with the first conductive layer in the first direction. A first end of the c conductive layer is in contact with a second end of the second conductive layer, and a second end of the first conductive layer is away from the second end of the second conductive layer. A material of the second conductive layer is different from a material of the first conductive layer.

In some implementations, a value of a work function of the material of the second conductive layer is higher than a value of a work function of the material of the first conductive layer.

In some implementations, the material of the first conductive layer includes at least one of Aluminum, Tungsten, Titanium, Molybdenum, or Platinum. The material of the second conductive layer includes at least one of TiN or polysilicon.

In some implementations, a ratio of a length of the second conductive layer along the first direction to a length of the first conductive layer along the first direction ranges from 1 to 10.

In some implementations, a length of the first conductive layer or the second conductive layer along the first direction ranges from 10 nm to 100 nm.

In some implementations, a thickness of the first conductive layer or a second conductive layer in a second direction ranges from 5 nm to 8 nm, the second direction being perpendicular to the first direction.

In some implementations, a thickness of the second conductive layer along a second direction is equal to or greater than a thickness of the first conductive layer along the second direction, the second direction being perpendicular to the first direction.

In some implementations, the memory device further includes an isolation structure between the gate structures of two adjacent transistors and extending beyond a top surface of the gate structure along the first direction.

In some implementations, a length of the gate structure along the first direction is equal to a sum of a length of the first conductive layer and a length of the second conductive layer along the first direction.

In some implementations, the gate structure further includes a third conductive layer in contact with a second end of the first conductive layer in the first direction. The first conductive and the third conductive layer do not overlap in the first plane, and a material of the third conductive layer being different from the material of the first conductive layer.

In some implementations, a length of the gate structure along the first direction is equal to a sum of a length of the first conductive layer, a length of the second conductive layer, and a length of the third conductive layer along the first direction.

In some implementations, the first conductive layer and the second conductive layer do not overlap in a first plane parallel to the first direction.

Some aspects of the present disclosure provide a memory device including an array of transistors extending along a first direction and word lines coupled to a respective row of transistors and extending along a third direction. Each word line includes a first word line layer extending along a first direction and a second word line layer contacting with a first end of the first word line layer along the first direction, the first direction is perpendicular to the third direction. A second end of the second word line layer is in contact with a first end of the first word line layer, and a first end of the second word line layer is away from the first end of the first conductive layer. A material of the second word line layer is different from a material of the first word line layer.

In some implementations, a value of a work function of the material of the second word line layer is higher than a value of a work function of the material of the first word line layer.

In some implementations, the material of the first word line layer includes at least one of Aluminum, Tungsten, Titanium, Molybdenum, or Platinum. The material of the second word line layer includes at least one of TiN or polysilicon.

In some implementations, a ratio of a length of the second word line layer along the first direction to a length of the first word line layer along the first direction ranges from 1 to 10.

In some implementations, a length of the first word line layer or the second word line layer along the first direction ranges from 10 nm to 100 nm.

In some implementations, a thickness of the first word line layer or the second word line layer along a second direction ranges from 5 nm to 8 nm, the second direction being perpendicular to the first direction and third direction.

In some implementations, a thickness of the second word line layer in a second direction is equal to or greater than a thickness of the first word line layer along the second direction, the second direction is perpendicular to the first direction.

In some implementations, the memory device further includes an isolation structure between two adjacent transistors and extending beyond a top surface of the word lines along the first direction.

In some implementations, a dimension of the word line along the first direction is equal to a sum of a dimension of the first word line layer and a dimension of the second word line layer.

In some implementations, each word line further includes a third word line layer contacting with a second end of the first word line layer along the first direction. A material of the third word line layer is different from a material of the first word line layer.

In some implementations, a length of the word line along the first direction is equal to a sum of a length of the first word line layer, a length of the second word line layer, and a length of the third word line layer along the first direction.

In some implementations, the first word line layer and the second word line layer do not overlap in a first plane parallel to the first direction.

Some aspects of the present disclosure provide a method for fabricating a memory device, including forming a semiconductor body on a substrate and forming a gate structure coupled with the semiconductor body along a first direction. The gate structure is formed of forming a first conductive layer extending along the first direction and forming a second conductive layer in contact with a first end of the first conductive layer along the first direction. The first end of the first conductive layer is in contact with a second end of the second conductive layer, and a second end of the first conductive layer is away from the second end of the second conductive layer. A material of the second conductive layer is different from a material of the first conductive layer.

In some implementations, forming the first conductive layer includes forming a gate dielectric layer covering a surface of the semiconductor body; forming a first layer covering the gate dielectric layer, the first layer has a same material as the first conductive layer; and removing a first end of the first layer.

In some implementations, forming the first conductive layer further includes truncating a second end of the first layer.

In some implementations, forming the second conductive layer includes forming a second layer above the first conductive layer and covering the gate dielectric layer, and removing a first end of the second layer to form the second conductive layer. A second end of the second layer is in contact with the first end of the first conductive layer.

In some implementations, forming the gate structure further includes forming a third conductive layer in contact with a second end of the first conductive layer along the first direction and a material of the third conductive layer is different from the material of the first conductive layer.

In some implementations, the third conductive layer is formed before forming the first conductive layer.

In some implementations, forming the third conductive layer includes forming a gate dielectric layer covering a surface of the semiconductor body; forming a third layer covering the gate dielectric layer, the third layer has a same material as the third conductive layer; and removing a first end of the third layer.

In some implementations, forming the first conductive layer includes forming a first layer above the third conductive layer and covering the gate dielectric layer and removing a first end of the first layer. A second end of the first layer is in contact with a first end of the third conductive layer.

In some implementations, forming the second conductive layer includes forming a second layer above the first conductive layer and covering the gate dielectric layer and removing a first end of the second layer. A second end of the second layer is in contact with a first end of the first conductive layer.

In some implementations, the third conductive layer is formed after forming the second conductive layer.

In some implementations, forming the third conductive layer includes: forming a gate dielectric layer covering a surface of the semiconductor body; forming a first layer covering the gate dielectric layer, the first layer has a same material as the first conductive layer; removing a first end of the first layer; forming a second layer covering the gate dielectric layer, a second end of the second layer is in contact with a first end of the first conductive layer; removing a first end of the second layer; forming a third layer covering the gate dielectric layer, a first end of the third layer is in contact with a second end of the first conductive layer; and removing a second end of the third layer to form the third conductive layer.

In some implementations, a value of a work function of the material of the second conductive layer is higher than a value of a work function of the material of the first conductive layer.

In some implementations, the material of the first conductive layer includes at least one of aluminum, tungsten, titanium, molybdenum, or platinum; and the material of the second conductive layer includes at least one of TiN or polysilicon.

In some implementations, a ratio of a length of the second conductive layer along the first direction to a length of the first conductive layer along the first direction ranges from 1 to 10.

In some implementations, a length of the first conductive layer along the first direction ranges from 10nm to 100 nm; or a length of the second conductive layer along the first direction ranges from 10 nm to 50 nm.

In some implementations, a thickness of the first conductive layer or the second conductive layer along a second direction ranges from 5 nm to 8 nm, the second direction being perpendicular to the first direction.

In some implementations, a thickness of the second conductive layer along a second direction is equal to or greater than a thickness of the first conductive layer along the second direction, the second direction is perpendicular to the first direction.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1A illustrates a schematic circuit diagram of a semiconductor device including an array of memory cells according to some implementations of the present disclosure.

FIG. 1B illustrates a schematic diagram of a vertical transistor, according to some implementations of the present disclosure.

FIG. 2 illustrates a partially schematic cross-sectional view of a semiconductor device, according to some implementations of the present disclosure.

FIGS. 3A-3B illustrate partially schematic cross-sectional views of different semiconductor devices, according to some implementations of the present disclosure.

FIG. 4 illustrates a flowchart of a fabricating method for forming a semiconductor device, according to some implementations of the present disclosure.

FIGS. 5A-5J each illustrates a schematic view of the semiconductor device at a certain fabricating stage of the method shown in FIG. 4, according to various implementations of the present disclosure.

FIG. 6 illustrates a flowchart of a fabricating method for forming a semiconductor device, according to some implementations of the present disclosure.

FIGS. 7A-7G each illustrates a schematic view of the semiconductor device at a certain fabricating stage of the method shown in FIG. 6, according to various implementations of the present disclosure.

FIG. 8 illustrates a flowchart of a fabricating method for forming a semiconductor device, according to some implementations of the present disclosure.

FIGS. 9A-9E each illustrates a schematic view of the semiconductor device at a certain fabricating stage of the method shown in FIG. 8, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Drain-Induced Barrier Lowering (DIBL) is a short-channel effect commonly observed in field-effect transistors (FETs), particularly in nanometer-scale transistors. DIBL occurs when a high drain voltage lowers the potential barrier between the source and the drain. This reduction in the barrier leads to a decrease in the transistor's threshold voltage and an increase in the subthreshold leakage current. As a result, power consumption increases, potentially compromising reliability. In 3D memory devices where memory cells (or memory layers) are stacked vertically in multiple layers for higher memory density, improved performance, and reduced footprint, the performance of the transistors in the corresponding memory cells is significantly impacted by DIBL.

For example, in vertical dynamic random access memory (DRAM) cells, a precise threshold voltage is critical for proper switching and retention of data. If DIBL excessively lowers the threshold voltage of the transistor, it could cause unexpected leakage current when the transistor is off, leading to data corruption or unwanted conduction between the access transistor and the storage node (capacitor). This could result in incorrect charge retention and loss of data. Further, increased leakage current can cause increased noise in the bit line and interfere with data sensing, especially in read operations where the stored charge on the capacitor is sensitive. Additionally, excessive leakage can lead to faster charge loss from the storage capacitor, decreasing the retention time of the memory cell, which may reduce the overall refresh rate and affect cell stability. Memory cells rely on the accurate reading of the charge stored in the capacitors. If the access transistor is improperly turned on (due to DIBL), it can cause incorrect reading of the stored data or data degradation. For example, if the access transistor leaks excessively, it could allow charge to flow out of the capacitor during the read operation, disturbing the charge and potentially causing bit flipping or data errors.

To address one or more of the aforementioned issues, the present disclosure introduces a memory device in which the gate structure of the transistor in each memory cell includes a first conductive layer extending along a first direction and a second conductive layer in contact with the first conductive layer in the first direction, the second conductive layer is closer to a drain region of the vertical transistor compared to the first conductive layer. In the present disclosure, a value of a work function of a material of the second conductive layer is lower than a value of a work function of a material of the first conductive layer. Therefore, the potential barrier decrease of the channel region covered by the second portion would be greatly suppressed, while the gate control ability would not be affected as the first portion has a higher value of the work function. Compared to a gate structure formed of a single conductive material, the negative effects of DIBL are suppressed effectively, while the gate control capability of the vertical transistors remains unaffected.

Consistent with the scope of the present disclosure, according to some implementations of the present disclosure, the disclosed memory device further includes a third conductive layer in contact with a second end of the first conductive layer in the first direction. A material of the third conductive layer is different from the material of the first conductive layer. The voltage difference between the source region and the drain region is different during the read operations and the write operations. For example, in some implementations, the voltage of the source region is higher than the voltage of the drain region during a read operation, and the voltage of the source region is lower than the voltage of the drain region during a write operation. To better suppress DIBL, the two ends of the gate structure are both replaced with materials having a lower work function value, ensuring that the transistor would not be affected by DIBL during either read or write operations.

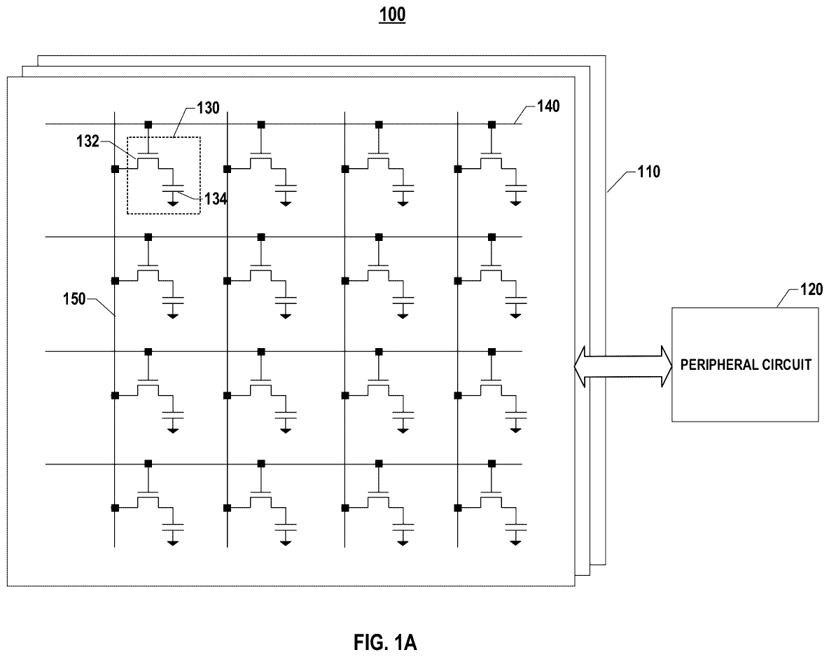

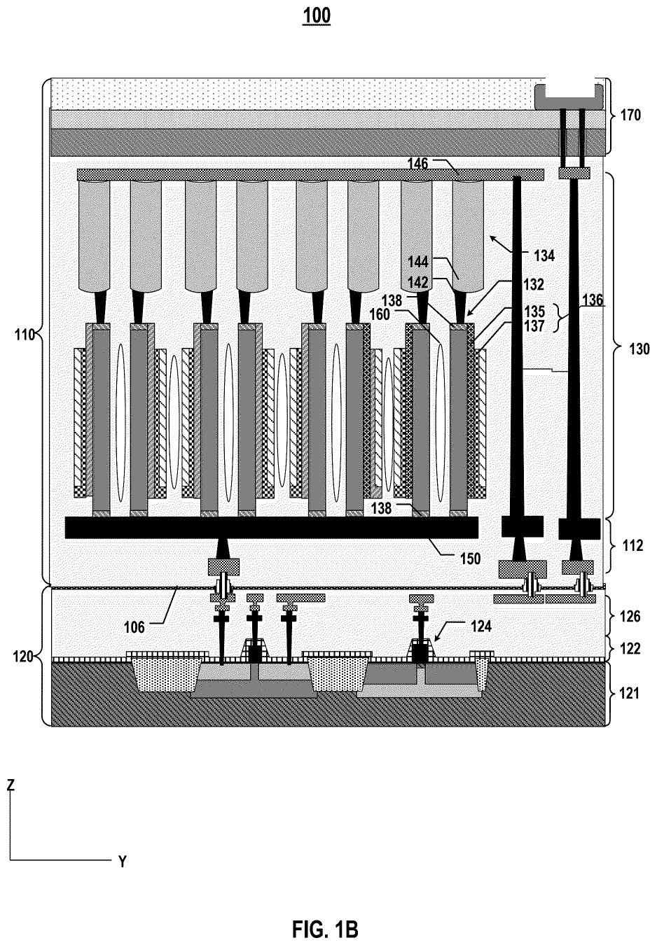

FIG. 1A illustrates a schematic diagram of a semiconductor device 100 including peripheral circuit structures and an array of memory cells each having a vertical transistor, according to some aspects of the present disclosure. Semiconductor device 100 can include a memory cell array 110 and peripheral circuit structures 120 coupled to memory cell array 110. Memory cell array 110 can be any suitable memory cell array in which each memory cell 130 includes a vertical transistor 132 and a capacitor 134 coupled to vertical transistor 132. In some implementations, memory cell array 110 is a memory cell array, and capacitor 134 is a capacitor for storing charge as the binary information stored by the respective memory cell. As shown in FIG. 1A, memory cells 130 can be arranged in a two-dimensional (2D) array having rows and columns. Peripheral circuit structures 120 can include any suitable digital, analog, and/or mixed-signal circuits used for facilitating the operations of the memory cell array. For example, the peripheral circuit structure can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuit structures 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuit structures 120 and memory cell array 110 for controlling the switch of vertical transistors 132 in memory cells 130 located in a row, as well as bit lines 150 coupling peripheral circuit structures 120 and memory cell array 110 for sending data to and/or receiving data from memory cells 130 located in a column. That is, each word line 140 is coupled to a respective row of memory cells 130, and each bit line 150 is coupled to a respective column of memory cells 130.

FIG. 1B illustrates a side view of a cross-section of semiconductor device 100 including peripheral circuit structures and an array of memory cells each having a vertical transistor, according to some aspects of the present disclosure. Semiconductor device 100 may include single-gate vertical transistors in which gate structures abut a single side of semiconductor bodies in the plan view. It is understood that FIG. 1B is for illustrative purposes only and may not necessarily reflect the actual device structure (e.g., interconnections) in practice. In some implementations, semiconductor device 100 is a bonded chip, memory cell array 110 is formed on a first semiconductor structure, and peripheral circuit structures 120 is formed on a second semiconductor structure, the first and second semiconductor structures are stacked along the first direction. The first and second semiconductor structures are joined at bonding interface 106 therebetween, according to some implementations.

Peripheral circuit structures 120 can include peripheral circuits 122 on substrate 121. In some implementations, peripheral circuits 122 include a plurality of transistors 124 (e.g., planar transistors and/or 3D transistors). Trench isolations (e.g., shallow trench isolations (STIs)) and doped regions (e.g., wells, sources, and drains of transistors 132) can be formed on or in substrate 121 as well. In some implementations, peripheral circuit structures 120 further includes an interconnect layer 126 above peripheral circuits 122 to transfer electrical signals to and from peripheral circuits 122. Interconnect layer 126 can include a plurality of interconnects (also referred to herein as “contacts”), including lateral interconnect lines and VIA contacts. Interconnect layer 126 can further include one or more ILD layers in which the interconnect lines and via contacts can form. That is, interconnect layer 126 can include interconnect lines and via contacts in multiple ILD layers. In some implementations, peripheral circuits 122 are coupled to one another through the interconnects in interconnect layer 126.

Memory cell array 110 can be bonded on top of peripheral circuit structures 120 in a face-to-face manner at bonding interface 106. In some implementations, memory cell array 110 can be formed on peripheral circuit structures 120 directly. Memory cell array 110 can include an interconnect layer 112 including bit lines 150 to transfer electrical signals. Interconnect layer 112 can include a plurality of interconnects, such as MEOL interconnects and BEOL interconnects.

In some implementations, memory cell array 110 includes a DRAM device in which memory cells are provided in the form of an array of memory cells 130 above interconnect layer 112. It is understood that the cross-section of semiconductor device 100 in FIG. 1B may be made along the bit line direction (the y-direction), and one bit line 150 in interconnect layer 112 extending laterally in the y-direction may be coupled to a column of memory cells 130. Each memory cell 130 can include a vertical transistor 132 and capacitor 134 coupled to the vertical transistor 132. memory cell 130 can be a 1T1C cell consisting of one transistor and one capacitor. It is understood that memory cell 130 may be of any suitable configurations, such as 2T1C cell, 3T1C cell, etc.

Vertical transistor 132 can be a MOSFET used to switch a respective memory cell 130. In some implementations, vertical transistor 132 includes a semiconductor body (i.e., the active region in which a channel can form) extending vertically (in the z-direction), and a gate structure 136 in contact with one side of semiconductor body in the bit line direction (the y-direction). As described above, as in a single-gate vertical transistor, semiconductor body can have a cuboid shape or a cylinder shape, and gate structure 136 can abut a single side of semiconductor body in the plan view. Gate structure 136 includes a gate electrode 137 and a gate dielectric 135 laterally between gate electrode 137 and semiconductor body in the bit line direction, according to some implementations. In some implementations, gate dielectric 135 abuts one side of semiconductor body, and gate electrode 137 abuts gate dielectric 135.

As shown in FIG. 1B, in some implementations, semiconductor body has two ends (the upper end and lower end) in the vertical direction (the z-direction), and at least one end extends beyond gate dielectric 135 in the vertical direction (the z-direction) into ILD layers. In some implementations, one end of the semiconductor body is flush with the respective end of gate dielectric 135. In some implementations, both ends of semiconductor body extend beyond gate electrode 137, respectively, in the vertical direction (the z-direction) into ILD layers. That is, semiconductor body can have a larger vertical dimension (e.g., the depth) than that of gate electrode 137 (e.g., in the z-direction), and neither the upper end nor the lower end of semiconductor body is flush with the respective end of gate electrode 137. Vertical transistor 132 can further include a source and a drain (both referred to as 138 as their locations may be interchangeable) disposed at the two ends (the upper end and lower end) of semiconductor body, respectively, in the vertical direction (the z-direction). In some implementations, one of source and drain 138 is coupled to capacitor 134, and the other one of source and drain 138 is coupled to bit line 150.

In some implementations, semiconductor body includes semiconductor materials, such as single crystalline silicon, polysilicon, amorphous silicon, Ge, any other semiconductor materials, or any combinations thereof. In one example, semiconductor body may include single crystalline silicon. Source and drain 138 can be doped with N-type dopants (e.g., P or As) or P-type dopants (e.g., B or Ga) at a desired doping level. In some implementations, a silicide layer, such as a metal silicide layer, is formed between source and drain 138 and bit line 150 to reduce the contact resistance. In some implementations, gate dielectric 135 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 137 includes conductive materials including, but not limited to W, Co, Cu, Al, TiN, TaN, polysilicon, silicides, or any combination thereof. In some implementations, gate electrode 137 includes multiple conductive layers, such as a W layer over a TiN layer, as shown in FIG. 1B. In one example, gate structure 136 may be a “gate oxide/gate poly” gate in which gate dielectric 135 includes silicon oxide and gate electrode 137 includes doped polysilicon. In another example, gate structure 136 may be an HKMG in which gate dielectric 135 includes a high-k dielectric and gate electrode 137 includes a metal.

As described above, gate electrodes 137 may be part of a word line or extend in a third direction, i.e., a word line direction perpendicular to the first and second direction, as a word line. Memory cell array 110 can also include a plurality of word lines each extending in the word line direction. Each word line can be coupled to a row of memory cells 130. Word lines are in contact with word line contacts (not shown), according to some implementations. In some implementations, word lines include conductive materials including, but not limited to W, Co, Cu, Al, TiN, TaN, polysilicon, silicides, or any combination thereof. In some implementations, word line includes multiple conductive layers, such as a W layer over a TiN layer, as shown in FIG. 1B.

As shown in FIG. 1B, vertical transistor 132 extends vertically through and contacts word lines, and source or drain 138 of vertical transistor 132 at the lower end thereof is in contact with bit line 150 (or bit line contact if any), according to some implementations. Accordingly, word lines and bit lines 150 can be disposed in different planes in the vertical direction due to the vertical arrangement of vertical transistor 132, which simplifies the routing of word lines and bit lines 150. In some implementations, bit lines 150 are disposed vertically between bonding layer and word lines, and word lines are disposed vertically between bit lines 150 and capacitors 134. Word lines can be coupled to peripheral circuits 122 in peripheral circuit structures 120 through word line contacts (not shown) in interconnect layer 112. Similarly, bit lines 150 in interconnect layer 112 can be coupled to peripheral circuits 122 in peripheral circuit structures 120.

As shown in FIG. 1B, vertical transistors 132 can be arranged in a mirror-symmetric manner to increase the density of memory cells 130 in the bit line direction (the y-direction). Two adjacent vertical transistors 132 in the bit line direction are mirror-symmetric to one another with respect to a trench isolation 160, according to some implementations. That is, memory cell array 110 can include a plurality of trench isolations 160 each extending in the word line direction (the x-direction) in parallel with word lines and disposed between semiconductor bodies of two adjacent rows of vertical transistors 132. In some implementations, the rows of vertical transistors 132 separated by trench isolation 160 are mirror-symmetric to one another with respect to trench isolation 160. Trench isolation 160 can be formed with dielectric materials including, but not limited to, silicon oxide, silicon nitride, silicon oxynitride, low-k dielectrics, or any combination thereof. It is understood that trench isolation 160 may include an air gap each disposed laterally between adjacent semiconductor bodies. As described below with respect to the fabrication process, air gaps may be formed due to the relatively small pitches of vertical transistors 132 in the bit line direction (e.g., the y-direction). On the other hand, the relatively large dielectric constant of air in air gaps (e.g., 4 times of the dielectric constant of silicon oxide) can improve the insulation effect between vertical transistors 132 (and rows of memory cells 130) compared to some dielectrics (e.g., silicon oxide). Similarly, in some implementations, air gaps are formed laterally between word lines/gate electrodes in the bit line direction as well, depending on the pitches of word lines/gate electrodes in the bit line direction.

As shown in FIG. 1B, in some implementations, capacitor 134 includes a first electrode 142 above and in contact with source or drain 138 of vertical transistor 132, e.g., the upper end of semiconductor body. Capacitor 134 can also include a capacitor dielectric 144 above and in contact with first electrode 142, and a second electrode 146 above and in contact with capacitor dielectric 144. That is, capacitor 134 can be a vertical capacitor in which electrodes 142 and 146 and capacitor dielectric 144 are stacked vertically (in the z-direction), and capacitor dielectric 144 can be sandwiched between electrodes 142 and 146. In some implementations, each first electrode 142 is coupled to source or drain 138 of a respective vertical transistor 132 in the same memory cell, while all second electrodes 146 are parts of a common plate coupled to the ground, e.g., a common ground. As shown in FIG. 1B, memory cell array 110 can further include a capacitor contact in contact with the common plate of second electrodes 146 for coupling second electrodes 146 of capacitor 134 to peripheral circuits 122 or to the ground directly. In some implementation, the ILD layer in which capacitors 134 are formed has the same dielectric material as the two ILD layers into which semiconductor body extends, such as silicon oxide.

It is understood that the structure and configuration of capacitor 134 are not limited to the example in FIG. 1B and may include any suitable structure and configuration, such as a planar capacitor, a stack capacitor, a multi-fins capacitor, a cylinder capacitor, a trench capacitor, or a substrate-plate capacitor. In some implementations, capacitor dielectric 144 includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, capacitor 134 may be a ferroelectric capacitor used in a FRAM cell, and capacitor dielectric 144 may be replaced by a ferroelectric layer having ferroelectric materials, such as (PZT or SBT. In some implementations, electrodes 142 and 146 include conductive materials including, but not limited to W, Co, Cu, Al, TiN, TaN, polysilicon, silicides, or any combination thereof.

As shown in FIG. 1B, vertical transistor 132 extends vertically through and contacts word lines, source or drain 138 of vertical transistor 132 at the lower end thereof is in contact with bit line 150, and source or drain 138 of vertical transistor 132 at the upper end thereof is in contact with electrode 142 of capacitor 134, according to some implementations. That is, bit line 150 and capacitor 134 can be disposed in different planes in the vertical direction and coupled to opposite ends of vertical transistor 132 of memory cell 130 in the vertical direction due to the vertical arrangement of vertical transistor 132. In some implementations, bit line 150 and capacitor 134 are disposed on opposite sides of vertical transistor 132 in the vertical direction, which simplifies the routing of bit lines 150 and reduces the coupling capacitance between bit lines 150 and capacitors 134 compared to conventional memory cells in which the bit lines and capacitors are disposed on the same side of the planar transistors.

As shown in FIG. 1B, in some implementations, vertical transistors 132 are disposed vertically between capacitors 134 and bonding interface 106. That is, vertical transistors 132 can be arranged closer to peripheral circuits 122 of peripheral circuit structures 120 and bonding interface 106 than capacitors 134. Since bit lines 150 and capacitors 134 are coupled to opposite ends of vertical transistors 132, as described above, bit lines 150 (as part of interconnect layer 112) are disposed vertically between vertical transistors 132 and bonding interface 106, according to some implementations. As a result, interconnect layer 112 including bit lines 150 can be arranged close to bonding interface 106 to reduce the interconnect routing distance and complexity.

As shown in FIG. 1B, memory cell array 110 can further include a pad-out interconnect layer 170 above memory cells 130. Pad-out interconnect layer 170 can include interconnects in one or more ILD layers. Pad-out interconnect layer 170 and interconnect layer 112 can be formed on opposite sides of memory cells 130. Capacitors 134 are disposed vertically between vertical transistors 132 and pad-out interconnect layer 170, according to some implementations. In some implementations, the interconnects in pad-out interconnect layer 170 can transfer electrical signals between semiconductor device 100 and outside circuits, e.g., for pad-out purposes. In some implementations, memory cell array 110 further includes one or more contacts extending through part of pad-out interconnect layer 170 to couple pad-out interconnect layer 170 to memory cells 130 and interconnect layer 112.

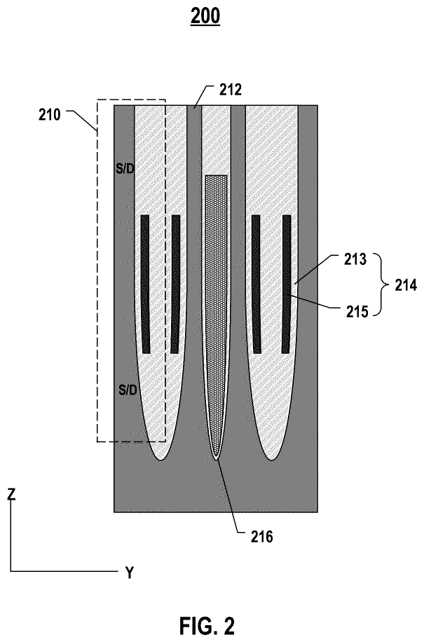

FIG. 2 illustrates a side view of a partial cross-section of a memory device 200 having a plurality of vertical transistors 210 extending along a first direction, i.e., the z-direction. Vertical transistor 210 can be Gate-All-Around (GAA) vertical transistors, tri-Gate vertical transistors, double gate vertical transistors, or single gate vertical transistors. In some implementations, vertical transistors 210 include Mirror Single-Gate (MSG) vertical transistors, characterized by the symmetric arrangement of the gate structures of two adjacent vertical transistors, as shown in FIG. 2. In some implementations, vertical transistor 210 can include a pair of a source and a drain S/D formed at the two ends of a semiconductor body 212 respectively. Vertical transistor 210 can also include a gate structure 214 coupled with one or more lateral sides of semiconductor body 212 in the first direction. Gate structure 214 can include a gate dielectric 213 over one or more sides of semiconductor body 212 and a gate electrode 215 over and coupled with gate dielectric 213. A conductive layer 216 is formed between two adjacent vertical transistors and is surrounded by dielectric materials. A length of conductive layer 216 is longer than a length of gate electrode 215 in the first direction to suppress the coupling-induced leakage between the two transistors. In some implementations, conductive layer 216 extends beyond the first end of the second conductive layer 317 and the second end of first conductive layer 315 along the first direction.

As the size of gate structure 214 keeps decreasing with the development of semiconductor technology, the performance of vertical transistors 210 is significantly impacted by DIBL. For example, unexpected leakage current will occur when the vertical transistor 210 is off, leading to data corruption or unwanted conduction between the vertical transistors 210 and corresponding capacitors (not shown in FIG. 2). This could result in incorrect charge retention and loss of data. Further, increased leakage current can cause increased noise in bit lines and interfere with data sensing, especially in read operations where the capacitor is sensitive. Additionally, excessive leakage can lead to faster charge loss from corresponding capacitors, decreasing the retention time of memory device 200.

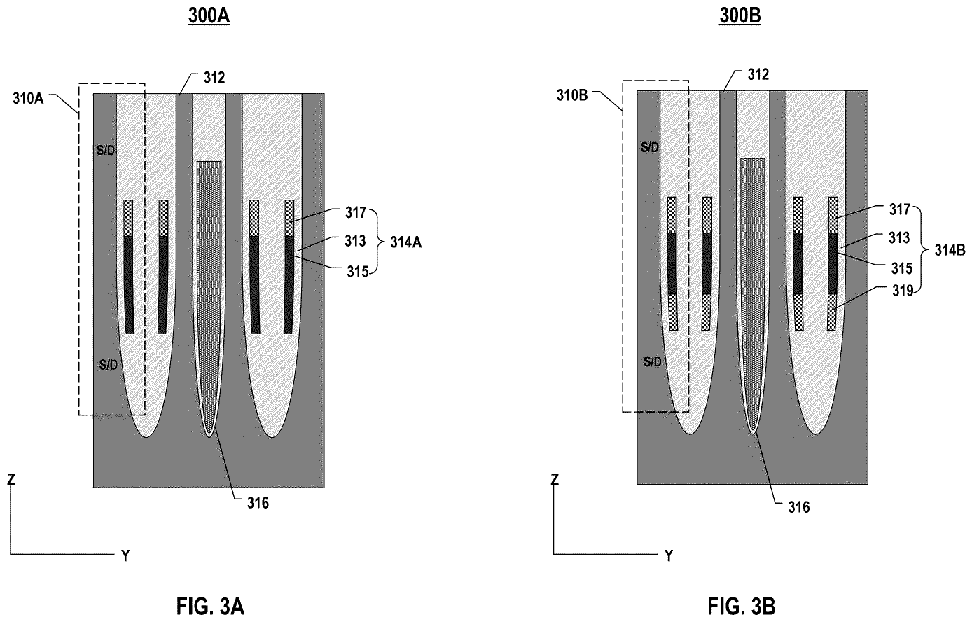

FIG. 3A illustrates a side view of a partial cross-section of a memory device 300A having a plurality of vertical transistors 310A extending along a first direction, i.e., the z-direction. It is understood that FIG. 3A is for illustrative purposes only and may not necessarily reflect the actual device structure in practice. As shown in FIG. 3A, vertical transistor 310A can include a pair of a source and a drain S/D formed at the two ends of a semiconductor body 312, respectively. Semiconductor body 312 can include silicon (e.g., single crystalline silicon, c-Si), silicon germanium (SiGe), gallium arsenide (GaAs), germanium (Ge), silicon-on-insulator (SOI), or any other suitable materials. Vertical transistor 310A can also include a gate structure 314A coupled with one or more lateral sides of semiconductor body 312 in the first direction. Gate structure 314A can include a gate dielectric 313 over one or more sides of semiconductor body 312 and a gate electrode over and coupled with gate dielectric 313. In some implementations, gate dielectric 313 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

A conductive layer 316 is formed between two adjacent vertical transistors and is surrounded by dielectric materials. In some implementations, the conductive layer 316 includes conductive materials including, but not limited to W, Co, Cu, Al, TiN, TaN, polysilicon, silicide, or any combination thereof. In some implementations, conductive layer 316 includes multiple conductive layers, such as a W layer over a TiN layer. In some implementations, a length of conductive layer 316 is longer than a length of gate electrode in the first direction to suppress the coupling-induced leakage between the two transistors.

Referring to FIGS. 2 and 3A, memory device 300A is distinguished from memory device 200 in the structure of the gate electrodes of the corresponding vertical transistors 210 and 310A. Vertical transistor 310A includes a first conductive layer 315 extending along the first direction and a second conductive layer 317 in contact with the first conductive layer 315 in the first direction. A material of second conductive layer 317 is different from a material of the first conductive layer 315. First conductive layer 315 includes a second end away from second conductive layer 317 and a first end in contact with second conductive layer 317. The first end and second end of first conductive layer 315 are opposite to each other in the first direction. Second conductive layer 317 includes a second end in contact with the first end of first conductive layer 315 and a first end away from first conductive layer 315. The first end and second end of second conductive layer 317 are opposite to each other in the first direction. In some implementations, first conductive layer 315 and the second conductive layer 317 do not overlap in a first plane parallel to the first direction. A length of gate structure 314A along the first direction is equal to a sum of a length of first conductive layer 315 and a length of second conductive layer 317 along the first direction.

According to some aspects of the present disclosure, memory device 300A includes an array of vertical transistors 310A and an array of capacitors coupled with the vertical transistors 310A, respectively. Memory device 300A can include a plurality of word lines each extending in a third direction (the x-direction), and a plurality of bit lines each extending in a second direction perpendicular to the first lateral direction (the y-direction). The word lines couple to a respective row of vertical transistors 310A and extend along a third direction, i.e., the x-direction. The plurality of bit lines and the array of capacitors are arranged at two sides of the array of vertical transistors 310A in the first direction. It is understood that gate electrodes of vertical transistors 310A and corresponding word lines may be a continuous conductive structure in some examples. In other words, gate electrodes of vertical transistors 310A may be part of the word lines, and the word lines may be extensions of corresponding gate electrodes. That is, gate electrodes of adjacent vertical transistors 310A are continuous in the third direction. Gate dielectrics 313 of adjacent vertical transistors 310A are continuous in the third direction, e.g., parts of a continuous dielectric layer having gate dielectrics 313 and extending in the third direction to abut vertical transistors in the same row on the same side. Gate structures 314A can be viewed as parts of a continuous structure extending in the third direction at which the continuous structure abuts vertical transistors 310A is in the same row on the same side.

In some implementations, the word lines of memory device 300A have a similar structure of the gate electrodes of gate structure 314A. That is, the word line includes a first word line layer extends along a first direction, and a second word line layer contacts with a first end of the first word line layer along the first direction. A second end of the second word line layer is in contact with a first end of the first word line layer, and a first end of the second word line layer is away from the first end of the first word line layer. In some implementations, the first word line layer includes the first conductive layers 315 of the vertical transistor 310A that coupled with the word line, the first conductive layers 315 of each vertical transistor 310A may be part of the corresponding first word line layer. That is, the first word line layer may be extensions of corresponding first conductive layers 315. In some implementations, the second word line layer includes the second conductive layers 317 of the vertical transistor 310A that coupled with the word line, the second conductive layers 317 of each vertical transistor 310A may be part of the corresponding second word line layer. That is, the second word line layer may be extensions of corresponding second conductive layers 317.

As shown in FIG. 3A, first conductive layer 315 covers a middle region of a channel of vertical transistor 310A, and second conductive layer 317 is closer to one of the source and drain S/D regions than first conductive layer 315. As discussed above, when a voltage difference is generated between the first end of first conductive layer 315 and the second end of second conductive layer 317, for example, when the second end of second conductive layer 317 suffers a higher voltage, the threshold voltage of second conductive layer 317 would be reduced and cause unexpected leakage current when vertical transistor 310A is off. In some implementations of the present disclosure, to solve this question, a value of a work function of the material of second conductive layer 317 is higher than a value of a work function of the material of first conductive layer 315. That is, compared to first conductive layer 315, second conductive layer 317 would need a higher minimum voltage to invert the surface of semiconductor body 312 and create a conductive channel between the source and drain. Therefore, the threshold voltage decrease caused by DIBL would be mitigated and even eliminated as the effects generated by the voltage difference are offset by the work function difference between first conductive layer 315 and second conductive layer 317.

In some implementations, first conductive layer 315 and second conductive layer 317 are formed of the same conductive material with different iron doping levels, because the value of work function of the conductive material is sensitive to the iron doped therein. For example, doping with iron (Fe) generally increases the work function of a metal by adding electron density, while doping with boron (B) generally decreases the work function by introducing hole states. In some implementations, first conductive layer 315 may be formed of undoped metal, such as Aluminum, Tungsten, Titanium, Molybdenum, and Platinum, while second conductive layer 317 may be formed of the same metal doped with iron (Fe). In some implementations, first conductive layer 315 may be formed of metal doped with boron (B), while second conductive layer 317 may be formed of the same undoped metal. In some implementations, first conductive layer 315 and second conductive layer 317 are formed of different conductive materials. For example, first conductive layer 315 may be formed of Aluminum, Tungsten, Titanium, Molybdenum, or Platinum, while second conductive layer 317 may be formed of TiN or polysilicon. It should be noted that the implementations are illustrative, and the material of first conductive layer 315 and second conductive layer 317 in the implementations of the present disclosure should not be explained as limits to the present disclosure.

FIG. 3B illustrates a side view of a partial cross-section of a memory device 300B having a plurality of vertical transistors 310B extending along a first direction, i.e., the z-direction. As shown in FIG. 3B, vertical transistor 310B can include a pair of a source and a drain S/D formed at the two ends of a semiconductor body 312 respectively. Vertical transistor 310B can also include a gate structure 314B coupled with one or more lateral sides of semiconductor body 312 in the first direction. Gate structure 314B can include a gate dielectric 313 over one or more sides of semiconductor body 312 and a gate electrode over and coupled with gate dielectric 313. A conductive layer 316 is formed between two adjacent vertical transistors and is surrounded by dielectric materials. A length of conductive layer 316 is longer than a length of gate electrode in the first direction to suppress the coupling-induced leakage between the two transistors.

According to some aspects of the present disclosure, memory device 300B includes an array of vertical transistors 310B and an array of capacitors coupled with the vertical transistors 310B, respectively. Memory device 300B can include a plurality of word lines each extending in a third direction (the x-direction) and a plurality of bit lines each extending in a second direction perpendicular to the first lateral direction (the y-direction). The word lines couple to a respective row of vertical transistors 310B and extend along a third direction, i.e., the x-direction. The plurality of bit lines and the array of capacitors are arranged at two sides of the array of vertical transistors 310B in the first direction. It is understood that gate electrode of vertical transistors 310B and corresponding word lines may be a continuous conductive structure in some examples. In other words, gate electrode of vertical transistors 310B may be part of the word lines, and the word lines may be extensions of corresponding gate electrodes. That is, gate electrodes of adjacent vertical transistors 310B are continuous in the third direction. Gate dielectrics 313 of adjacent vertical transistors 310B are continuous in the third direction, e.g., parts of a continuous dielectric layer having gate dielectrics 313 and extending in the third direction to abut vertical transistors in the same row on the same side. Gate structures 314B can be thus viewed as parts of a continuous structure extending in the third direction at which the continuous structure abut vertical transistors 310B in the same row on the same side.

In some implementations, each word line of memory device 300B has a similar structure of the gate electrodes of gate structure 314B. That is, the word line includes a first word line layer extends along a first direction, a second word line layer in contact with a first end of the first word line layer along the first direction, and a third word line layer in contact with a second end of the first word line layer along the first direction. A second end of the second word line layer is in contact with a first end of the first word line layer, and a first end of the second word line layer is away from the first end of the first word line layer. A first end of the third word line layer is in contact with a second end of the first word line layer, and a second end of the third word line layer is away from the second end of the first word line layer. In some implementations, the first word line layer includes the first conductive layers 315 of the vertical transistor 310B that coupled with the word line, the first conductive layers 315 of each vertical transistor 310B may be part of the corresponding first word line layer. That is, the first word line layer may be extensions of corresponding first conductive layers 315. In some implementations, the second word line layer includes the second conductive layers 317 of the vertical transistor 310B that coupled with the word line, the second conductive layers 317 of each vertical transistor 310B may be part of the corresponding second word line layer. That is, the second word line layer may be extensions of corresponding second conductive layers 317. In some implementations, the third word line layer includes the third conductive layers 319 of the vertical transistor 310B that coupled with the word line, the third conductive layers 319 of each vertical transistor 310B may be part of the corresponding third word line layer. That is, the third word line layer may be extensions of corresponding third conductive layers 319.

As shown in FIG. 3B, first conductive layer 315 covers a middle region of a channel of vertical transistor 310B, second conductive layer 317 and third conductive layer 319 cover two ends of the channel of vertical transistor 310B that are close to the source and drain S/D region respectively. As discussed above, when a voltage difference is generated between the first end of first conductive layer 315 and the second end of third conductive layer 319, for example, when the second end of third conductive layer 319 experiences a higher voltage, the threshold voltage of third conductive layer 319 is reduced, causing unexpected leakage current when vertical transistor 310B is off. In some implementations of the present disclosure, to solve this question, a value of a work function of the material of second conductive layer 317 and third conductive layer 319 should be higher than a value of a work function of the material of first conductive layer 315. That is, compared with first conductive layer 315, second conductive layer 317, and third conductive layer 319 would need a higher minimum voltage to invert the surface of semiconductor body 312 and create a conductive channel between the source and drain. Therefore, the threshold voltage decrease caused by DIBL would be mitigated and even eliminated as the effects generated by the voltage difference are offset by the work function difference between different conductive layers.

Referring to FIGS. 3A and 3B, memory device 300B distinguishes from memory device 300A in the structure of the gate electrode of the corresponding vertical transistors 310A and 310B. Vertical transistor 310B includes first conductive layer 315 extending along the first direction, second conductive layer 317 in contact with the first end of first conductive layer 315 in the first direction, and a third conductive layer 319 in contact with the second end of first conductive layer 315 in the first direction. Second conductive layer 317, first conductive layer 315, and third conductive layer 319 are arranged in order along the first direction. A material of second conductive layer 317 and third conductive layer 319 is different from a material of the first conductive layer 315. First conductive layer 315 is located in the middle of the channel region and includes the first end in contact with second conductive layer 317 and the second end in contact with third conductive layer 319. The first end and second end of first conductive layer 315 are opposite to each other in the first direction. Second conductive layer 317 includes a first end away from first conductive layer 315 and a second end in contact with the first end of first conductive layer 315. The first end and second end of second conductive layer 317 are opposite to each other in the first direction. Third conductive layer 319 includes a first end in contact with the second end of first conductive layer 315 and a second end away from the first end of first conductive layer 315. The first end and second end of third conductive layer 319 are opposite to each other in the first direction.

In some implementations, first conductive layer 315, the second conductive layer 317, and third conductive layer 319 do not overlap in a first plane parallel to the first direction. A length of gate structure 314B along the first direction is equal to a sum of a length of first conductive layer 315, a length of second conductive layer 317, and a length of third conductive layer 319 along the first direction.

As shown in FIG. 3B, first conductive layer 315 covers a middle region of a channel of vertical transistor 310B, second conductive layer 317 is closer to one of the source and drain S/D region, and third conductive layer 319 is closer to another one of the source and drain S/D region. As discussed above, when a voltage difference is generated between the first end of first conductive layer 315 and the second end of third conductive layer 319, the threshold voltage of second conductive layer 317 or third conductive layer 319 would be reduced, and cause unexpected leakage current when vertical transistor 310B is off. In some implementations, a voltage applied to the first end of second conductive layer 317 is higher than a voltage applied to the second end of the third conductive layer 319, such as in a write operation. In some implementations, a voltage applied to the first end of second conductive layer 317 is lower than a voltage applied to the second end of the third conductive layer 319, such as in a read operation.

In some implementations, to solve this issue, a value of a work function of the material of second conductive layer 317 and third conductive layer 319 should be higher than a value of a work function of the material of first conductive layer 315. That is, compared to first conductive layer 315, second conductive layer 317, and third conductive layer 319 would need a higher minimum voltage to invert the surface of semiconductor body 312 and create a conductive channel between the source and drain. Therefore, the threshold voltage decrease caused by DIBL would be mitigated and even eliminated as the effects generated by the voltage difference is offset by the work function difference. The material of second conductive layer 317 and third conductive layer 319 may be the same or different. In some implementations, first conductive layer 315, second conductive layer 317, and third conductive layer 319 are formed of the same conductive material with different iron doping levels, because the value of the work function of the conductive material is sensitive to the iron doped therein. For example, doping with iron (Fe) generally increases the work function of a metal by adding electron density, while doping with boron (B) generally decreases the work function by introducing hole states. In some implementations, first conductive layer 315 may be formed of undoped metal, such as Aluminum, Tungsten, Titanium, Molybdenum, and Platinum, while second conductive layer 317 and third conductive layer 319 may be formed of same metal doped with iron (Fe). In some implementations, first conductive layer 315 may be formed of metal doped with boron (B), while second conductive layer 317 and third conductive layer 319 may be formed of the same undoped metal. In some implementations, first conductive layer 315, second conductive layer 317, and third conductive layer 319 are formed of different conductive materials, for example, first conductive layer 315 may be formed of Aluminum, Tungsten, Titanium, Molybdenum, or Platinum, while second conductive layer 317 and third conductive layer 319 may be formed of TiN or polysilicon. It should be noted that the implementations are illustrative, and the material of first conductive layer 315, second conductive layer 317, and third conductive layer 319 in the implementations of the present disclosure should not be explained as limits to the present disclosure.

In some implementations, the first conductive layer 315, second conductive layer 317, and third conductive layer 319 can be formed on gate dielectric 313 by deposition processes including, but not limited to, chemical vapor deposition (CVD), physical vapor deposition (PVD), atomic layer deposition (ALD), or any combination thereof. Therefore, the conductive layers may be thin films with a thickness much smaller than their width. In some implementations, a length of the gate electrode ranges from 10 nm to 200 nm depending on the size of corresponding memory device and fabrication processes. In some implementations, a length of first conductive layer 315 is greater than a half of the length of the gate electrode. For example, a length of first conductive layer 315 is less than the length of the gate electrode and ranges from 10 nm to 100 nm. In some implementations, a length of second conductive layer 317 is equal to a length of third conductive layer 319. In some implementations, a ratio of a length of second conductive layer 317 along the first direction to a length of first conductive layer 315 along the first direction ranges from 1 to 10. For example, the length of first conductive layer 315 is 100 nm, the length of second conductive layer 317 and the length of third conductive layer 319 are 10 nm. It should be noted that the lengths of first conductive layer 315, the second conductive layer 317, and the third conductive layer 319 can be designed as needed. The implementations in the present disclosure are illustrative and should not be explained as limits to the present disclosure.

In some implementations, a thickness of first conductive layer 315, a thickness of second conductive layer 317, and a thickness of third conductive layer 319 are equal to each other. In some implementations, the thickness of second conductive layer 317 and the thickness of third conductive layer 319 is equal to or greater than the thickness of first conductive layer 315 along the second direction, i.e., the y-direction, the second direction being perpendicular to the first direction. In some implementations, a thickness of each conductive layer in a second direction ranges from 5 nm to 8 nm. In some implementations, the thicknesses of them may be different due to fabrication deviation.

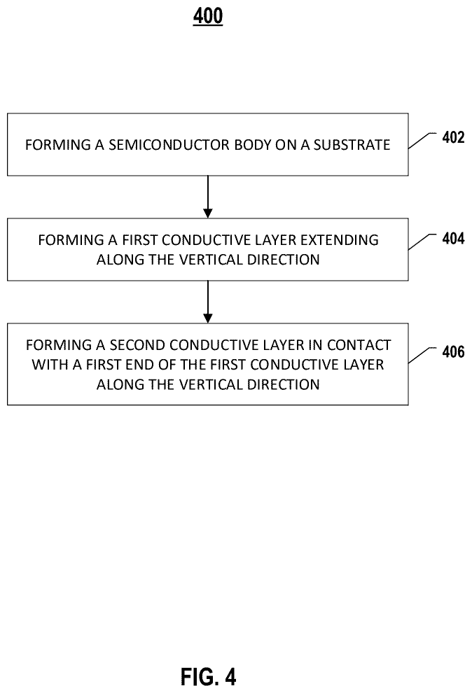

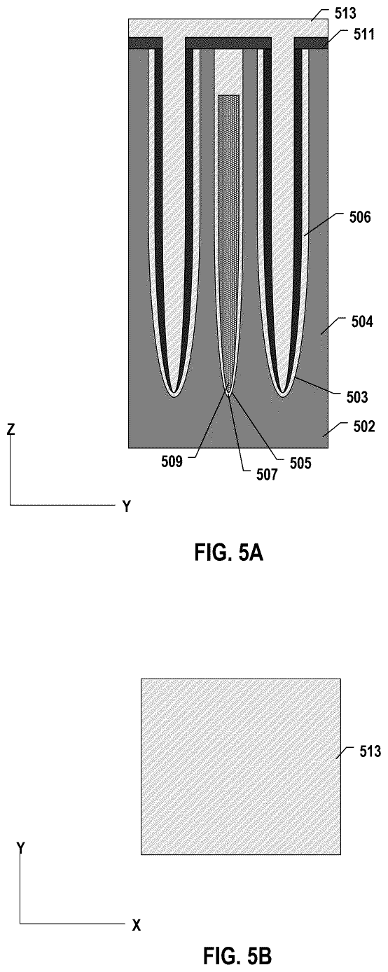

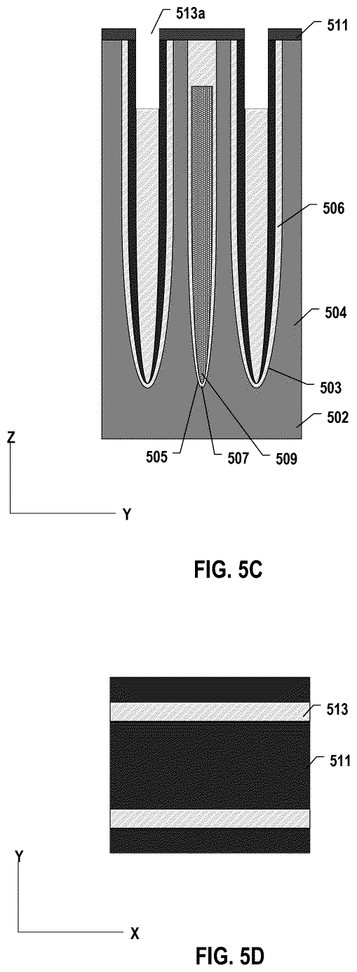

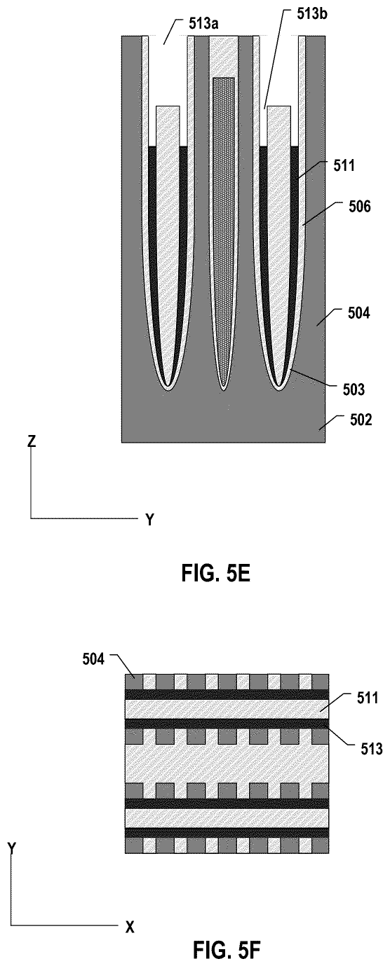

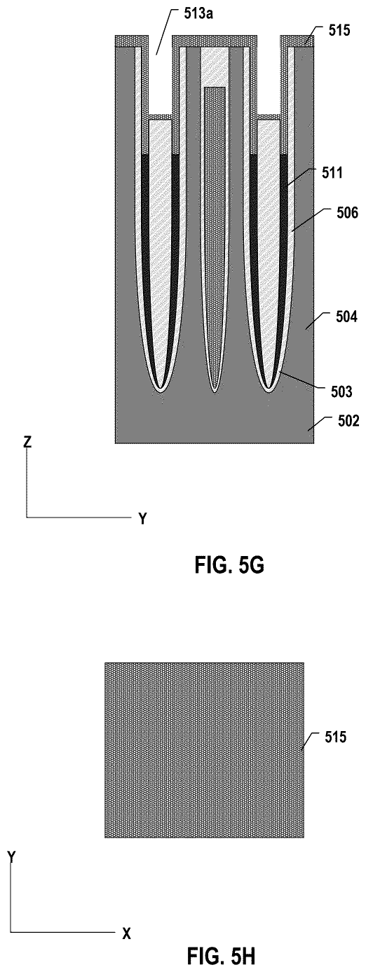

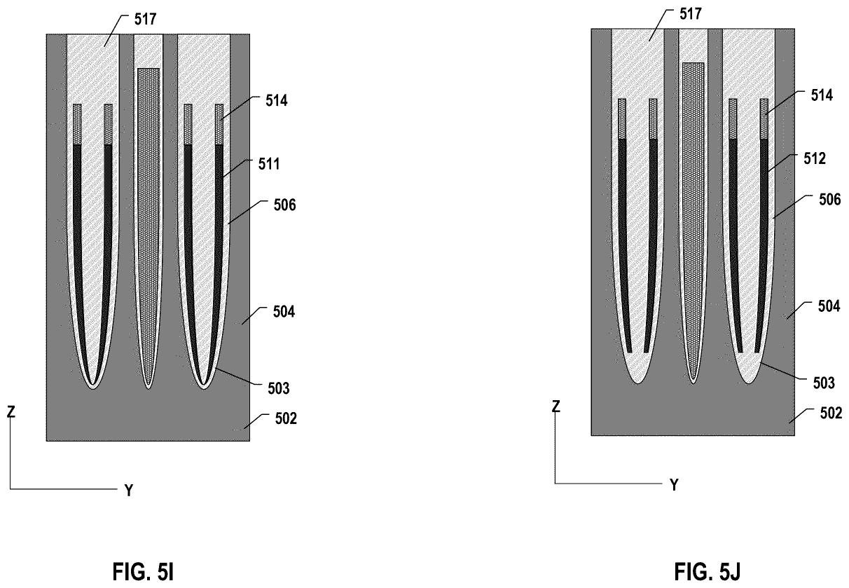

FIG. 4 illustrates a flowchart of a fabricating method 400 for forming a memory structure, according to some implementations of the present disclosure. FIGS. 5A-5J illustrate schematic views of a semiconductor device at certain fabricating stages of method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4.

As shown in FIGS. 4 and 5A, method 400 can start at operation 402, in which a plurality of semiconductor bodies 504 are formed on a substrate 502. Substrate 502 can include silicon (e.g., single crystalline silicon, c-Si), silicon germanium (SiGe), gallium arsenide (GaAs), germanium (Ge), silicon-on-insulator (SOI), or any other suitable materials. Semiconductor body 504 extends upward from substrate 502 along the first direction. As shown in FIG. 5A, two adjacent vertical transistors in the second direction are mirror-symmetric to one another. Gate structures of two adjacent vertical transistors are formed in a plurality of first trenches 503 between two semiconductor bodies 504 and the trench isolation layers can be formed in a plurality of second trenches 505 between two semiconductor bodies 504. The plurality of first trenches 503 and second trenches 505 are arranged alternatively as shown in FIG. 5A.

In some implementations, semiconductor bodies 504 of each pair of two adjacent vertical transistors in the second direction (the y-direction) can be formed of separating a semiconductor pillar into two pieces using a trench isolation formed in the second trenches 505. First trenches 503 and second trenches 505 can be disposed in an interleaved manner in the second direction. It is understood that in some examples, second trenches 505 and the trench isolation may not be formed such that two adjacent semiconductor bodies 504 separated by respective trench isolation may be merged as a single semiconductor layer having two opposite sides in the second direction coupled with gate structures. That is, without second trenches 505 and the trench isolations, the adjacent single-gate vertical transistors may be merged to form a double-gate vertical transistor with an increased gate control area and lower leakage current. The gate structure of the double-gate vertical transistor may include two mirror-symmetric gate structures in FIG. 5A, such that both sides of semiconductor body 504 in the second direction may be coupled with the gate structure in the double-gate vertical transistor.

In some implementations, the trench isolation may be formed of dielectric materials, such as silicon oxide or silicon nitride. In some implementations, the trench isolation may include air gaps formed within the dielectric materials. In some implementations, the trench isolation may include a conductive layer 509 surrounded by an isolating layer 507. Conductive layers 509 may include metal materials like copper, tungsten, or titanium nitride, or highly-doped semiconductors like silicon. Conductive layers 509 can be coupled to a common voltage source, such as common ground. Conductive layers 509 are used to prevent interference or crosstalk between two adjacent vertical transistors, ensuring they operate independently and efficiently.

As shown in FIG. 4 and FIGS. 5A-5G, method 400 can proceed to operations 404 and 406, in which a first conductive layer 512 and a second conductive layer 514 extending along the first direction are formed. FIGS. 5A-5G illustrate a schematic side cross-sectional view of the semiconductor device in the y-z plane during operations 404 and 406 of method 400.

Referring to FIG. 5A, gate dielectric layer 506 is formed on the surface of semiconductor body 504 in first trenches 503. In some implementations, gate dielectric layer 506 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. Gate dielectric layer 506 can be formed of a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc.)

In some implementations, a first layer 511 is then formed to cover gate dielectric layer 506. First layer 511 has the same material as the first conductive layer. First layer 511 may be formed of one or more thin film deposition processes including, but not limited to, CVD, PVD, ALD, or any combination thereof. The first trenches 503 can be filled with dielectric materials 513 after first layer 511 being formed, as shown in FIGS. 5A and 5B. FIG. 5A illustrates a schematic side cross-sectional view of the semiconductor device in the y-z plane after first layer 511 being formed. FIG. 5B illustrates a schematic side cross-sectional view of the semiconductor device in x-y plane after first layer 511 being formed.

In some implementations, as shown in FIGS. 5C and 5D, a top portion of the dielectric materials 513 filled in first trenches 503 is removed to expose a first end, i.e., a top end, of first layer 511. FIG. 5C illustrates a schematic side cross-sectional view of the semiconductor device in the y-z plane after the top portion of the dielectric materials 513 being removed. FIG. 5D illustrates a schematic side cross-sectional view of the semiconductor device in the x-y plane after the top portion of the dielectric materials 513 being removed. The dielectric materials 513 remained in the first trench 503 is then used as a hard mask to pattern first layer 511. A space 513a is formed above the remaining dielectric materials 513, as shown in FIG. 5C. In some implementations, the trench isolation extends beyond a top surface of the remaining dielectric materials 513, as shown in FIG. 5C.

Referring to FIGS. 5E and 5F, a first end of first layer 511 is then removed by etching processes, such as wet/dry etch, or any other suitable processes. FIG. 5E illustrates a schematic side cross-sectional view of the semiconductor device in the y-z plane after the first end of first layer 511 being removed. FIG. 5F illustrates a schematic side cross-sectional view of the semiconductor device in x-y plane after the first end of first layer 511 being removed. In some implementations, wet etch is applied to remove the top portion of first layer 511, and slits 513b will be created between gate dielectric layer 506 and the remaining dielectric materials 513 in first trenches 503. A top surface of first layer 511 is then exposed from slit 513b, as shown in FIG. 5F. In some implementations, a height of slit 513b in the first direction equals a height of the second conductive layer in the first direction.

Referring to FIGS. 5G and 5H, a second layer 515 is then formed, covering the semiconductor structure after the first end of first layer 511 being removed. Slits 513b are filled by second layer 515. FIG. 5G illustrates a schematic side cross-sectional view of the semiconductor device in the y-z plane after the second layer 515 being formed. FIG. 5H illustrates a schematic side cross-sectional view of the semiconductor device in the x-y plane after the second layer 515 being formed. Second layer 515 has the same material as the second conductive layer.

In some implementations, first layer 511 and second layer 515 are formed of the same conductive material with different iron doping levels, because the value of work function of the conductive material is sensitive to the iron doped therein. For example, doping with iron (Fe) generally increases the work function of a metal by adding electron density, while doping with boron (B) generally decreases the work function by introducing hole states. In some implementations, first layer 511 may be formed of undoped metal, such as Aluminum, Tungsten, Titanium, Molybdenum, and Platinum, while second layer 515 may be formed of the same metal doped with iron (Fe). In some implementations, first layer 511 may be formed of metal doped with boron (B), while second layer 515 may be formed of the same undoped metal. In some implementations, first layer 511 and second layer 515 are formed of different conductive materials. For example, first layer 511 may be formed of Aluminum, Tungsten, Titanium, Molybdenum, or Platinum, while second layer 515 may be formed of TiN or polysilicon. It should be noted that the implementations are illustrative, and the material of first layer 511 and second layer 515 in the implementations of the present disclosure should not be explained as limits to the present disclosure.

Referring to FIG. 5I, etching processes are performed on second layer 515 to remove the portion of second layer 515 that is outside slit 513b to form a second conductive layer 514. Then space 513a is filled with dielectric materials 517. A first end of second conductive layer 514 is away from first layer 511, a second end of second conductive layer 514 is in contact with a first end of first layer 511, as shown in FIG. 51. Second conductive layer 514 forms a part of the gate electrode of the corresponding vertical transistor and a part of the corresponding word line coupled with the vertical transistor. Because the value of the work function of second conductive layer 514 is higher than that of first conductive layer 512, the threshold reduction caused by DIBL could be offset by second conductive layer 514.

Referring to FIG. 5J, a second end of first layer 511 is truncated to form first conductive layer 512. In some implementations, the truncating process can be performed from a front side of the semiconductor structure by forming a trench extending through the dielectric materials between two adjacent gate electrodes. In some implementations, the truncating process can be performed from a back side of the semiconductor structure. In some implementations, as shown in FIG. 5J, the second end of the first conductive layer is nonlinear, depending on the fabrication processes. In some implementations, the second end of the first conductive layer is smoothly inclined towards the adjacent first conductive layer in the first direction. In some implementations, the second end of first conductive layer has an “L-shape” foot extending towards the adjacent conductive layer along the third direction.

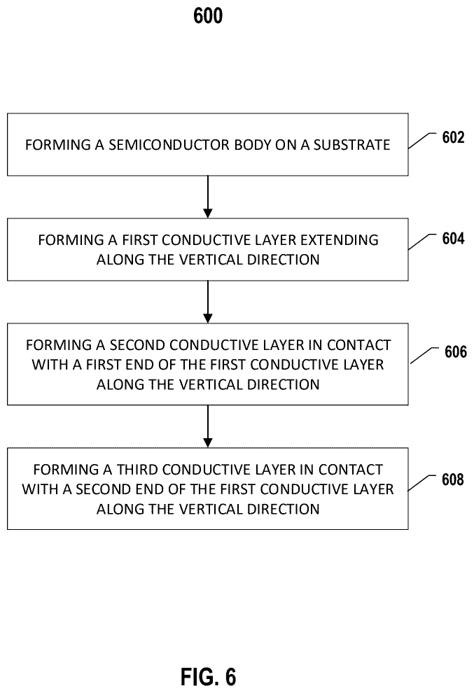

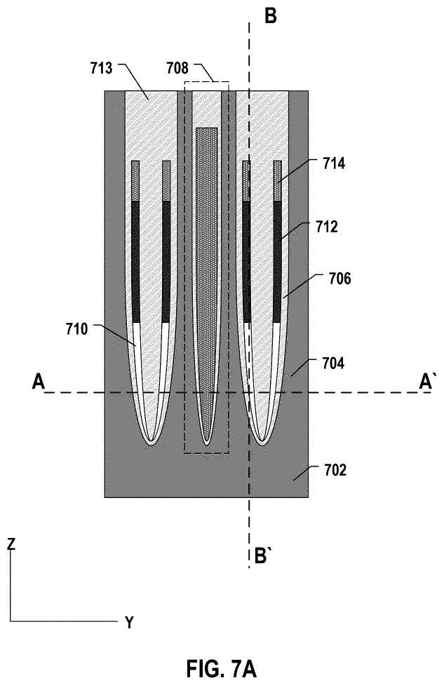

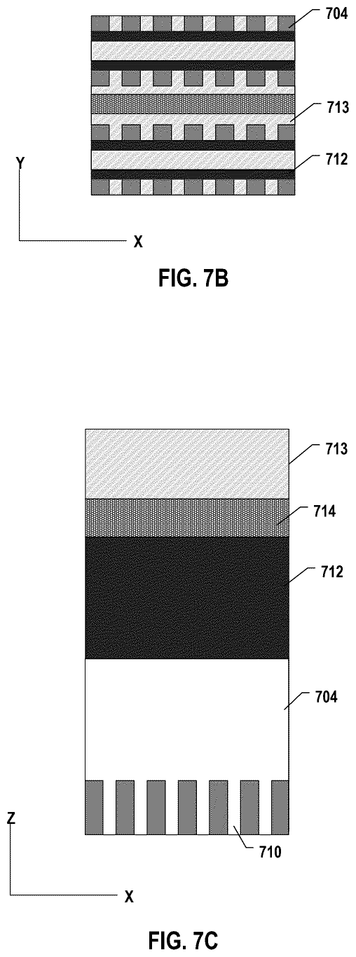

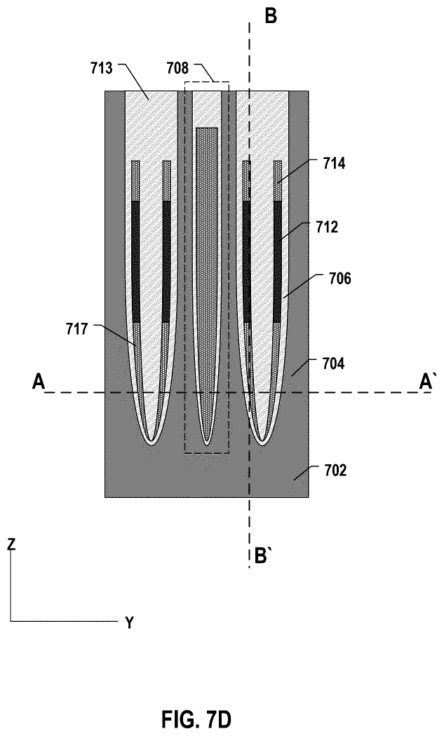

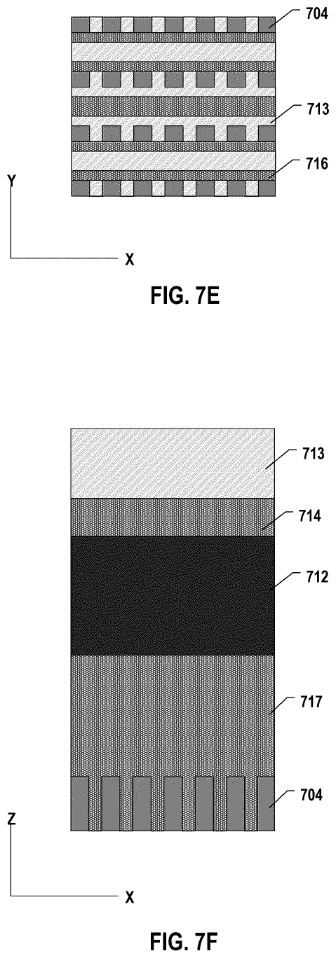

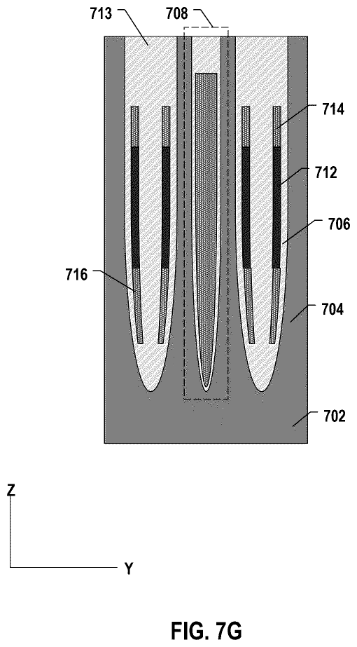

FIG. 6 illustrates a flowchart of a fabricating method 600 for forming a memory structure, according to some implementations of the present disclosure. FIGS. 7A-7G illustrate schematic views of a semiconductor device at certain fabricating stages of method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

In some implementations, operations 602, 604, and 606 in method 600 are the same as operations 404, 404, and 406, in which a first conductive layer 712 and a second conductive layer 714 is formed. Method 600 is distinguished from method 400 in operation 608, in which a third conductive layer 716 is formed after second conductive layer 714 being formed.

In some implementations, a plurality of slits 710 are formed from the back side of the semiconductor structure to expose the second end of first conductive layer 712 after the second conductive layer 714 being formed. Referring to FIGS. 7A-7C, FIG. 7A illustrates a schematic side cross-sectional view of the semiconductor device in y-z plane after slits 710 being formed. FIG. 7B illustrates a schematic side cross-sectional view of the semiconductor device in the x-y plane along AA′ direction after slits 710 being formed. FIG. 7C illustrates a schematic side cross-sectional view of the semiconductor device in the y-z plane along BB′ direction after slits 710 being formed.

Referring to FIG. 7A, a plurality of semiconductor bodies 704 are formed on substrate 702, and a plurality of gate dielectric layers 706 are formed covering the semiconductor bodies 704. An isolation trench 708 with a conductive layer is formed between two adjacent semiconductor bodies 704. Then first conductive layer 712 and second conductive layer 714 are formed to couple with gate dielectric layer 706. The structures and fabrication method of each component in FIG. 7A are similar to that shown in FIG. 5A to 5J and will not be repeated here to avoid redundance.

As shown in FIG. 4 and FIGS. 7A-7G, method 600 can proceed to operation 608, in which a third conductive layer 716 is formed in contact with first conductive layer 712. In some implementations, a value of a work function of the material of second conductive layer 714 and third conductive layer 716 is higher than a value of a work function of the material of first conductive layer 712. In some implementations, first conductive layer 712, second conductive layer 714, and third conductive layer 716 are formed of the same conductive material with different iron doping levels, because the value of work function of the conductive material is sensitive to the iron doped therein. For example, doping with iron (Fe) generally increases the work function of a metal by adding electron density, while doping with boron (B) generally decreases the work function by introducing hole states. In some implementations, first conductive layer 712 may be formed of undoped metal, such as Aluminum, Tungsten, Titanium, Molybdenum, and Platinum, while second conductive layer 714 and third conductive layer 716 may be formed of the same metal doped with iron (Fe). In some implementations, first conductive layer 712 may be formed of metal doped with boron (B), while second conductive layer 714 and third conductive layer 716 may be formed of the same undoped metal. In some implementations, first conductive layer 712, second conductive layer 714, and third conductive layer 716 are formed of different conductive materials. For example, first conductive layer 712 may be formed of Aluminum, Tungsten, Titanium, Molybdenum, or Platinum, while second conductive layer 714 and third conductive layer 716 may be formed of TiN or polysilicon.

To form third conductive layer 716 after the formation of the second conductive layer 714, in some implementations, slits 710 are formed from the back side of the semiconductor structure to expose the second end of first conductive layer 712 after the second conductive layer 714 being formed, as shown in FIGS. 7B and 7C. In some implementations, dielectric materials 713 is attached to a carrier substrate so that substrate 702 is upward for pattern processes. Referring to FIGS. 7A and 7C, slits 710 extend through substrate 702 to expose the second end of first conductive layer 712. In some implementations, back grinding is performed to thin substrate 702 before fabricating slits 710. Then a series of pattern processes, such as photolithography and etching are performed to form slits 710.

As shown in FIGS. 7D-7F, a third layer 717 is filled in slits 710 to form third conductive layer 716. FIG. 7D illustrates a schematic side cross-sectional view of the semiconductor device in the y-z plane after third layer 717 being formed. FIG. 7E illustrates a schematic side cross-sectional view of the semiconductor device in the x-y plane along AA direction after third layer 717 being formed. FIG. 7F illustrates a schematic side cross-sectional view of the semiconductor device in the y-z plane along BB′ direction after third layer 717 being formed.

Third layer 717 includes the same material as third conductive layer 716. Third layer 717 may be formed of one or more thin film deposition processes including, but not limited to, CVD, PVD, ALD, or any combination thereof. Thereafter, referring to FIG. 7G, etching processes are performed on third layer 717 to remove the portion of third layer 717 to form a third conductive layer 716. A second end of third conductive layer 716 is away from first layer 511, and a first end of third conductive layer 716 is in contact with the second end of first conductive layer 712, as shown in FIG. 7G. Third conductive layer 716 forms a part of the gate electrode of the corresponding vertical transistor and a part of the corresponding word line coupled with the vertical transistor. Because third conductive layer 716 has a higher work function than first conductive layer 712, the threshold decrease caused by DIBL could be offset by third conductive layer 716.

In some implementations, a length of first conductive layer 712 is greater than a half of the length of the gate electrode. For example, a length of first conductive layer 712 may range from 10 nm to 100 nm. In some implementations, a length of second conductive layer 714 is equal to a length of third conductive layer 716. In some implementations, a ratio of a length of second conductive layer 714 along the first direction to a length of first conductive layer 712 along the first direction ranges from 1 to 10. For example, the length of first conductive layer 712 is 100 nm, the length of second conductive layer 714, and the length of third conductive layer 716 are 10 nm. It should be noted that the lengths of first conductive layer 712, the second conductive layer 714, and the third conductive layer 716 can be designed as needed. The implementations in the present disclosure are illustrative and should not be explained as limits to the present disclosure.

In some implementations, a thickness of first conductive layer 712, a thickness of second conductive layer 714, and a thickness of third conductive layer 716 are equal to each other. In some implementations, the thickness of second conductive layer 714 and the thickness of third conductive layer 716 are equal to or greater than the thickness of first conductive layer 712 along the second direction, i.e., the y-direction, the second direction being perpendicular to the first direction. In some implementations, a thickness of each conductive layer in a second direction ranges from 5 nm to 8 nm. In some implementations, the thicknesses of them may be different due to fabrication deviation.

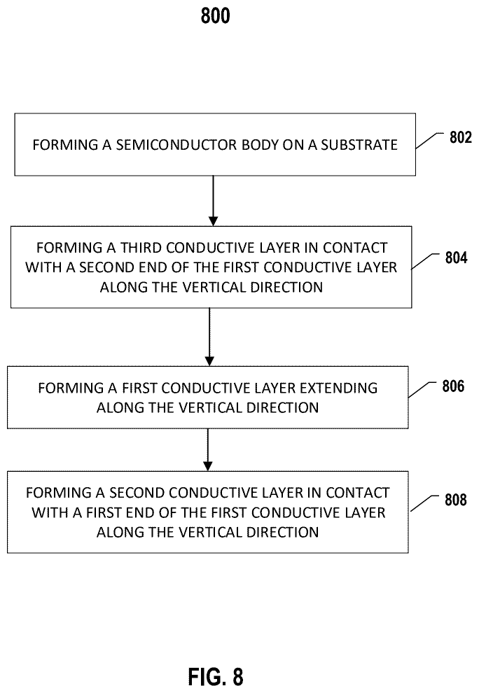

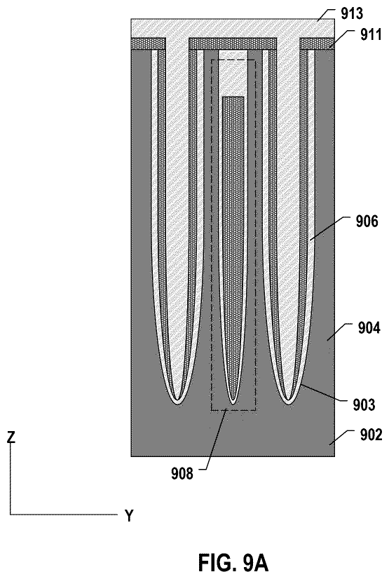

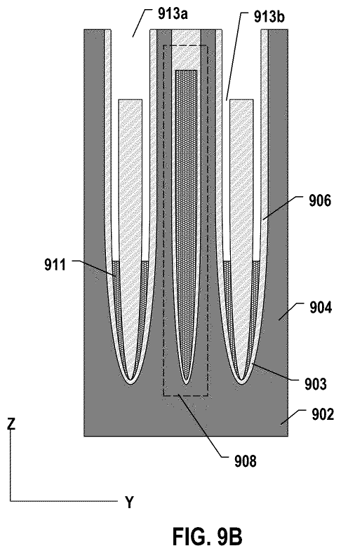

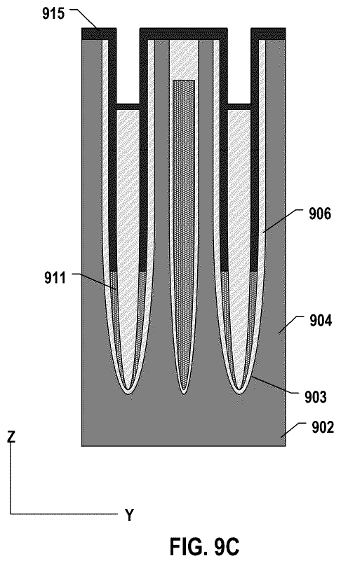

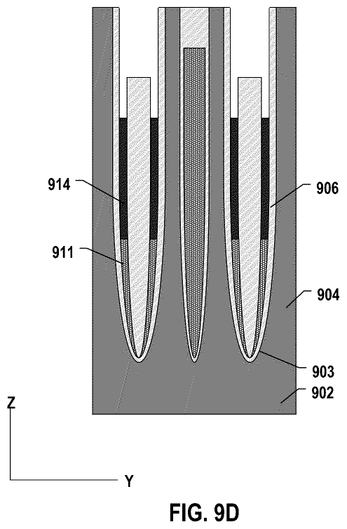

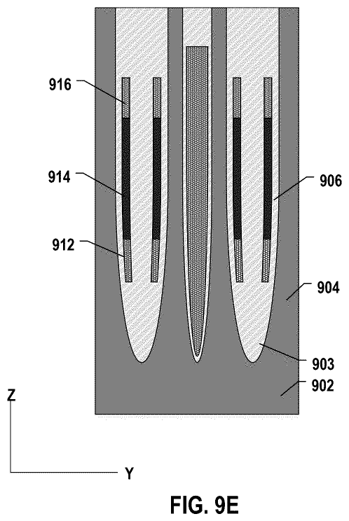

FIG. 8 illustrates a flowchart of a fabricating method 800 for forming a memory structure, according to some implementations of the present disclosure. FIGS. 9A-9E illustrate schematic views of a semiconductor device at certain fabricating stages of method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIGS. 8 and 9A, method 800 can start at operation 802, in which semiconductor bodies 904 are formed on a substrate 902. Substrate 902 and semiconductor body 904 may be the same as described above and will not be repeated here. As shown in FIG. 9A, two adjacent vertical transistors in the second direction are mirror-symmetric. Gate structures of two adjacent vertical transistors are formed in a plurality of first trenches 903 between two semiconductor bodies 904. Trench isolations 908 can be formed in a plurality of second trenches between two semiconductor bodies 504. The plurality of first trenches 503 and trench isolations 908 are arranged alternatively as shown in FIG. 9A. It is understood that in some examples, trench isolations 908 may not be formed such that two adjacent semiconductor bodies 904 separated by a respective trench isolation may be merged as a single semiconductor layer having two opposite sides in the second direction coupled with gate structures. That is, without trench isolations 908, the adjacent single-gate vertical transistors may be merged to form a double-gate vertical transistor with an increased gate control area and lower leakage current. In some implementations, trench isolation 908 may be formed of dielectric materials, such as silicon oxide or silicon nitride. In some implementations, trench isolation 908 may include air gaps formed within the dielectric materials. In some implementations, trench isolation 908 may include a conductive layer surrounded by an isolating layer.

As shown in FIG. 8 and FIG. 9A, method 800 can proceed to operation 804, in which a third conductive layer 912 is formed. Referring to FIG. 9A, gate dielectric layer 906 is formed on the surface of semiconductor body 904 in first trenches 903. Gate dielectric layer 906 can be formed of a series of fabricating processes including CVD, PVD, ALD, and patterning processes (e.g., photoetching, dry etching, wet etching, cleaning, etc.). In some implementations, a third layer 911 is then formed to cover gate dielectric layer 906. Third layer 911 has the same material as third conductive layer 912. Third layer 911 may be formed by one or more thin film deposition processes including, but not limited to, CVD, PVD, ALD, or any combination thereof. The first trenches 903 can be filled with dielectric materials 913 after third layer 911 being formed, as shown in FIG. 9A.

In some implementations, as shown in FIG. 9B, a top portion of the dielectric materials 913 filled in first trenches 903 is removed to expose a first end, i.e., a top end, of third layer 911. The dielectric materials 913 remained in the first trench 903 is then used as a hard mask to pattern third layer 911. A space 913a is formed above the remaining dielectric materials 913, as shown in FIG. 9B. In some implementations, the conductive layer of trench isolation 908 extends beyond a top surface of the remaining dielectric materials 913, as shown in FIG. 9B. Referring to FIG. 9B, a first end of third layer 911 is then removed by etching processes, such as wet/dry etch, or any other suitable processes. In some implementations, wet etch is applied to remove the top portion of third layer 911, and slits 913b will be created between gate dielectric layer 906 and the remaining dielectric materials 913 in first trenches 903. A top surface of third layer 911 is then exposed from slits 913b, as shown in FIG. 9B.

As shown in FIG. 8 and FIGS. 9C-9D, method 800 can start at operation 806, in which first conductive layer 914 is formed. Referring to FIGS. 9C and 9D, a first layer 915 is then formed, covering the semiconductor structure after the first end of third layer 911 being removed. Slits 913b are filled by first layer 915.

In some implementations, third layer 911 and first layer 915 are formed of the same conductive material with different iron doping levels, because the value of the work function of the conductive material is sensitive to the iron doped therein. For example, doping with iron (Fe) generally increases the work function of a metal by adding electron density, while doping with boron (B) generally decreases the work function by introducing hole states. In some implementations, first layer 915 may be formed of undoped metal, such as Aluminum, Tungsten, Titanium, Molybdenum, and Platinum, while third layer 911 may be formed of the same metal doped with iron (Fe). In some implementations, first layer 915 may be formed of metal doped with boron (B), while third layer 911 may be formed of the same undoped metal. In some implementations, first layer 915 and third layer 911 are formed of different conductive materials. For example, first layer 915 may be formed of Aluminum, Tungsten, Titanium, Molybdenum, or Platinum, while third layer 911 may be formed of TiN or polysilicon. It should be noted that the implementations are illustrative and the material of first layer 915 and third layer 911 in the implementations of the present disclosure should not be explained as being limited to the present disclosure.

Referring to FIG. 9D, etching processes are performed on first layer 915 to remove the portion of first layer 915 that outside slits 913b to form a first conductive layer 914. A first end of first conductive layer 914 is away from third layer 911, a second end of first conductive layer 914 is in contact with a first end of third layer 911, as shown in FIG. 9D. First conductive layer 914 forms a part of the gate electrode of the corresponding vertical transistor and a part of the corresponding word line coupled with the vertical transistor. In some implementations, top portions of slits 913b remain unfilled to form second conductive layer therein.

Referring to FIG. 8 and FIG. 9E, method 800 can start at operation 808, in which second conductive layer 916 is formed in slits 913b. In some implementations, a first layer (not shown) is then formed to cover the semiconductor structure after the first end of first layer 915 being removed. Slits 913b are filled by first layer 915. Then etching processes are performed on second layer to remove the portion of second layer that is outside slit 913b to form a second conductive layer 916. The detailed fabricating method of second conductive layer 916 may refer to the implementations described above and will not be repeated here.

Referring to FIG. 9E, a second end of third layer 911 is truncated to form third conductive layer 912. In some implementations, the truncating process can be performed from a front side of the semiconductor structure by forming a trench extending through the dielectric materials between two adjacent gate electrodes. In some implementations, the truncating process can be performed from a back side of the semiconductor structure.

In some implementations, a length of first conductive layer 914 is greater than a half of the length of the gate electrode. For example, a length of first conductive layer 914 may range from 10 nm to 100 nm. In some implementations, a length of second conductive layer 916 equals to a length of third conductive layer 912. In some implementations, a ratio of a length of second conductive layer 916 along the first direction to a length of first conductive layer 914 along the first direction ranges from 1 to 10. For example, the length of first conductive layer 914 is 100 nm, the length of second conductive layer 916, and the length of third conductive layer 912 are 10 nm. It should be noted that the lengths of first conductive layer 914, the second conductive layer 916, and the third conductive layer 912 can be designed as needed. The implementations in the present disclosure are illustrative and should not be explained as limits to the present disclosure.

In some implementations, a thickness of first conductive layer 914, a thickness of second conductive layer 916, and a thickness of third conductive layer 912 are equal. In some implementations, the thickness of second conductive layer 916 and the thickness of third conductive layer 912 equal to or greater than the thickness of first conductive layer 914 along the second direction. In some implementations, a thickness of each conductive layer in a second direction ranges from 5 nm to 8 nm. In some implementations, their thicknesses may be different due to fabrication deviation.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

1. A memory device comprising transistors, each transistor comprising:
a semiconductor body extending along a first direction; and
a gate structure coupled with the semiconductor body; wherein
the gate structure extends along the first direction, and comprises:
a first conductive layer extending along the first direction; and
a second conductive layer in contact with the first conductive layer in the first direction; wherein
a first end of the first conductive layer is in contact with a second end of the second conductive layer, and a second end of the first conductive layer is away from the second end of the second conductive layer; and
a material of the second conductive layer is different from a material of the first conductive layer.

2. The memory device of claim 1, wherein
a value of a work function of the material of the second conductive layer is higher than a value of a work function of the material of the first conductive layer.

3. The memory device of claim 1, wherein
the material of the first conductive layer comprises at least one of Aluminum, Tungsten, Titanium, Molybdenum, and Platinum; and
the material of the second conductive layer comprises at least one of TiN or polysilicon.

4. The memory device of claim 1, wherein
a ratio of a length of the second conductive layer along the first direction to a length of the first conductive layer along the first direction ranges from 1 to 10.

5. The memory device of claim 1, wherein
a length of the first conductive layer or the second conductive layer along the first direction ranges from 10 nm to 100 nm.

6. The memory device of claim 1, wherein
a thickness of the first conductive layer or a second conductive layer in a second direction ranges from 5 nm to 8 nm, the second direction being perpendicular to the first direction.

7. The memory device of claim 1, wherein
a thickness of the second conductive layer along a second direction is equal to or greater than a thickness of the first conductive layer along the second direction, the second direction being perpendicular to the first direction.

8. The memory device of claim 1, further comprising:
an isolation structure between the gate structures of two adjacent transistors and extending beyond a top surface of the gate structure along the first direction.

9. The memory device of claim 1, wherein
a length of the gate structure along the first direction is equal to a sum of a length of the first conductive layer and a length of the second conductive layer along the first direction.

10. The memory device of claim 1, wherein the gate structure further comprises:
a third conductive layer in contact with a second end of the first conductive layer in the first direction; wherein
the first conductive layer and the third conductive layer do not overlap in a first plane parallel to the first direction; and
a material of the third conductive layer being different from the material of the first conductive layer.

11. The memory device of claim 10, wherein
a length of the gate structure along the first direction is equal to a sum of a length of the first conductive layer, a length of the second conductive layer, and a length of the third conductive layer along the first direction.

12. The memory device of claim 1, wherein
the first conductive layer and the second conductive layer do not overlap in a first plane parallel to the first direction.

13. A memory device comprising:
an array of transistors extending along a first direction; and
word lines coupled to a respective row of transistors and extending along a third direction; wherein
each word line comprises:
a first word line layer extending along a first direction; and
a second word line layer contacting with a first end of the first word line layer along the first direction, the first direction is perpendicular to the third direction; wherein
a second end of the second word line layer is in contact with the first end of the first word line layer, and a first end of the second word line layer is away from the first end of the first word line layer; and
a material of the second word line layer is different from a material of the first word line layer.

14. The memory device of claim 13, wherein
a value of a work function of the material of the second word line layer is higher than a value of a work function of the material of the first word line layer.

15. A method for fabricating a memory device, comprising:
forming a semiconductor body on a substrate; and
forming a gate structure coupled with the semiconductor body along a first direction by:
forming a first conductive layer extending along the first direction; and
forming a second conductive layer in contact with a first end of the first conductive layer along the first direction; wherein
a first end of the first conductive layer is in contact with a second end of the second conductive layer, and a second end of the first conductive layer is away from the second end of the second conductive layer; and
a material of the second conductive layer is different from a material of the first conductive layer.

16. The method of claim 15, wherein forming the first conductive layer comprises:
forming a gate dielectric layer covering a surface of the semiconductor body;
forming a first layer covering the gate dielectric layer, the first layer has a same material as the first conductive layer; and
removing a first end of the first layer.

17. The method of claim 16, wherein forming the second conductive layer comprises:
forming a second layer above the first conductive layer and covering the gate dielectric layer; and
removing a first end of the second layer to form the second conductive layer;
wherein a second end of the second layer is in contact with the first end of the first conductive layer.

18. The method of claim 15, wherein forming the gate structure further comprises:
forming a third conductive layer in contact with a second end of the first conductive layer along the first direction; and
a material of the third conductive layer is different from the material of the first conductive layer.

19. The method of claim 18, wherein
the third conductive layer is formed before forming the first conductive layer; and forming the third conductive layer comprises:
forming a gate dielectric layer covering a surface of the semiconductor body;
forming a third layer covering the gate dielectric layer, the third layer has a same material as the third conductive layer;
removing a first end of the third layer;
forming a first layer above the third conductive layer and covering the gate dielectric layer;
removing a first end of the first layer;
wherein a second end of the first layer is in contact with a first end of the third conductive layer;
forming a second layer above the first conductive layer and covering the gate dielectric layer; and
removing a first end of the second layer;
wherein a second end of the second layer is in contact with a first end of the first conductive layer.

20. The method of claim 18, wherein
the third conductive layer is formed after forming the second conductive layer, and forming the third conductive layer comprises:
forming a gate dielectric layer covering a surface of the semiconductor body;
forming a first layer covering the gate dielectric layer, the first layer has a same material as the first conductive layer;
removing a first end of the first layer;
forming a second layer covering the gate dielectric layer, a second end of the second layer is in contact with a first end of the first conductive layer;
removing a first end of the second layer;
forming a third layer covering the gate dielectric layer, a first end of the third layer is in contact with a second end of the first conductive layer; and
removing a second end of the third layer to form the third conductive layer.
